(19) United States
(12) Patent Application Publication
(10) Pub. No.: US 2026/0165091 A1
(43) Pub. Date: Jun. 11, 2026

(54) SEMICONDUCTOR PACKAGE

(71) Applicant: SAMSUNG ELECTRONICS CO., LTD., Suwon-si (KR)

(72) Inventors: Keun Young LEE, Suwon-si (KR); Min-Woo KIM, Suwon-si (KR); Ki Won BAEK, Suwon-si (KR)

(73) Assignee: SAMSUNG ELECTRONICS CO., LTD., Suwon-si (KR)

(21) Appl. No.: 19/270,045

(22) Filed: Jul. 15, 2025

(30) Foreign Application Priority Data
Dec. 5, 2024 (KR) 10-2024-0179450

(51) Int. Cl. H01L 21/66; H01L 23/00; H01L 23/24; H01L 23/538; H01L 25/18; H10B 80/00; H10D 80/30

(52) U.S. Cl. CPC H10P 74/273; H10B 80/00; H10D 80/30; H10W 70/611; H10W 70/65; H10W 76/47; H10W 90/00; H10W 72/865; H10W 72/884; H10W 90/20; H10W 90/24; H10W 90/724; H10W 90/732; H10W 90/734; H10W 90/752; H10W 90/754

(57) ABSTRACT

There is provided a semiconductor package including a package substrate which includes an insulating film and a wiring structure, an external connection terminal and a test pad provided on a first surface of the package substrate, a first semiconductor chip provided on a second surface of the package substrate, test bumps and connection bumps provided between the second surface of the package substrate and the first semiconductor chip, and a second semiconductor chip provided on the second surface of the package substrate. The first semiconductor chip includes an on-chip connection line connected through internal wiring. The test bumps are connected to each other by the on-chip connection line, and the connection bumps are electrically connected to the external connection terminal by the wiring structure.

### CROSS-REFERENCE TO RELATED APPLICATION

This application is based on and claims priority from Korean Patent Application NO. 10-2024-0179450 filed on Dec. 5, 2024 in the Korean Intellectual Property Office, and all the benefits accruing therefrom under 35 U.S.C. 119, the contents of which in its entirely are herein incorporated by reference.

### BACKGROUND

### 1. Technical Field

The disclosure relates to a semiconductor package.

### 2. Description of the Related Art

Recently, electronic devices are becoming smaller and lighter in response to the rapid development of the electronics industry and the demands of users. As the electronic devices become smaller and lighter, semiconductor packages used in the electronic devices are also becoming smaller and lighter, and the semiconductor packages are required to have high reliability together with high performance and large capacity. In order to achieve small size, light weight, high performance, large capacity, and high reliability, research and development of semiconductor chips including through silicon via (TSV) and semiconductor packages of a structure in which the semiconductor chips are stacked in multiple stages are continuously being conducted.

### SUMMARY

Aspects of the disclosure provide a semiconductor package in which reliability is improved by detecting defects such as a short between bumps in a semiconductor package in which semiconductor chips are stacked.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an aspect of the disclosure, there is provided a semiconductor package including: a package substrate including an insulating film and a wiring structure; an external connection terminal provided on a first surface of the package substrate; a test pad provided on the first surface of the package substrate, and spaced apart from the external connection terminal; a first semiconductor chip provided on a second surface of the package substrate; a plurality of test bumps and a plurality of connection bumps provided between the second surface of the package substrate and the first semiconductor chip; and a second semiconductor chip provided on the second surface of the package substrate to be spaced apart from the first semiconductor chip, wherein the first semiconductor chip includes an on-chip connection line connected through an internal wiring, wherein at least two of the plurality of test bumps are connected to each other by the on-chip connection line, and wherein at least one of the plurality of connection bumps is electrically connected to the external connection terminal by the wiring structure.

According to another aspect of the disclosure, there is provided a semiconductor package including: a package substrate including an insulating film and a wiring structure; an external connection terminal provided on a first surface of the package substrate; a test pad provided on the first surface of the package substrate, and provided to be spaced apart from the external connection terminal; a first semiconductor chip provided on a second surface of the package substrate; a first test bump, a second test bump, and a connection bump provided between the second surface of the package substrate and the first semiconductor chip; a second semiconductor chip provided on the second surface of the package substrate; and a third semiconductor chip which is provided on the second surface of the package substrate, and spaced apart from the second semiconductor chip, wherein the first semiconductor chip includes an on-chip connection line connected through an internal wiring, wherein the first test bump and the second test bump are connected to each other by the on-chip connection line, wherein the first test bump is electrically connected to the second semiconductor chip and the test pad by the wiring structure, wherein the second test bump is electrically connected to the third semiconductor chip and the test pad by the wiring structure, and wherein the connection bump is electrically connected to the external connection terminal by the wiring structure.

According to another aspect of the disclosure, there is provided a semiconductor package including: a package substrate including an insulating film and a wiring structure; an external connection terminal which is provided on a first surface of the package substrate; a test pad which is provided on the first surface of the package substrate, and spaced apart from the external connection terminal; a controller provided on a second surface of the package substrate, the controller including a first region, and a second region that surrounds the first region; a plurality of test bumps and a plurality of connection bumps provided between the second surface of the package substrate and the controller; and a semiconductor chip stack provided on the second surface of the package substrate to be spaced apart from the controller, the semiconductor chip stack including a plurality of stacked memory chips, wherein the plurality of test bumps are provided in the second region, and electrically connected to the semiconductor chip stack and the test pad by the wiring structure, wherein the plurality of connection bumps are electrically connected to the external connection terminal by the wiring structure, wherein the controller includes on-chip connection lines connected through an internal wiring, wherein the plurality of test bumps are connected to each other by the on-chip connection lines, and wherein the semiconductor chip stack is wire-bonded to the package substrate.

It should be noted that the effects of the disclosure are not limited to those described above, and other effects of the disclosure will be apparent from the following description.

### BRIEF DESCRIPTION OF DRAWINGS

The above and other aspects and features of the disclosure will become more apparent by describing in detail illustrative embodiments thereof with reference to the attached drawings, in which:

FIG. 1 is a plan view for explaining a semiconductor package according to some embodiments of the disclosure.

FIG. 2 is a cross-sectional view taken along A-A′ of FIG. 1 according to some embodiments of the disclosure.

FIG. 3 is an enlarged view of portion B of FIG. 2 according to some embodiments of the disclosure.

FIG. 4 is a diagram showing a connection relationship between a lower surface of a controller of FIG. 1 and a test pad according to some embodiments of the disclosure.

FIG. 5 is a diagram showing a connection relationship between the lower surface of the controller of FIG. 1 and the test pad according to another embodiment of the disclosure.

FIG. 6 is a diagram showing a connection relationship between the lower surface of the controller of FIG. 1 and the test pad according to another embodiment of the disclosure.

FIG. 7 is a diagram showing a connection relationship between the lower surface of the controller of FIG. 1 and the test pad according to another embodiment of the disclosure.

FIG. 8 is a cross-sectional view taken along line A-A′ of FIG. 1 according to another embodiment of the disclosure.

FIG. 9 is a cross-sectional view of a semiconductor package according to another embodiment of the disclosure.

FIG. 10 is a cross-sectional view of a semiconductor package according to another embodiment of the disclosure.

FIG. 11 is a cross-sectional view of a semiconductor package according to another embodiment of the disclosure.

### DETAILED DESCRIPTION

In the disclosure, it will be understood that, although terms such as “first”, “second”, etc. may be used herein to describe various elements or components in the present specification, these elements or components are not limited by these terms. These terms are only used to distinguish a single element or component from other elements or components. Therefore, a first element or component discussed below may be a second element or component within the technical spirits of the disclosure.

The terminology used herein is for the purpose of describing particular embodiments only and is not intended to limit the disclosure. As used herein, the singular forms “a” and “an” are intended to include the plural forms as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entirety of list of elements and may not modify the individual elements of the list. When referring to “C to D”, this means C inclusive to D inclusive unless otherwise specified.

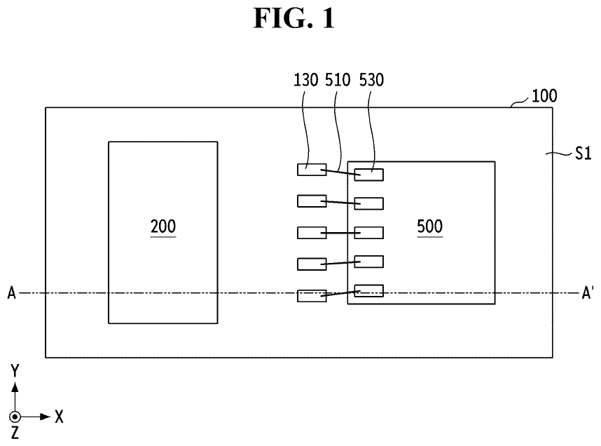

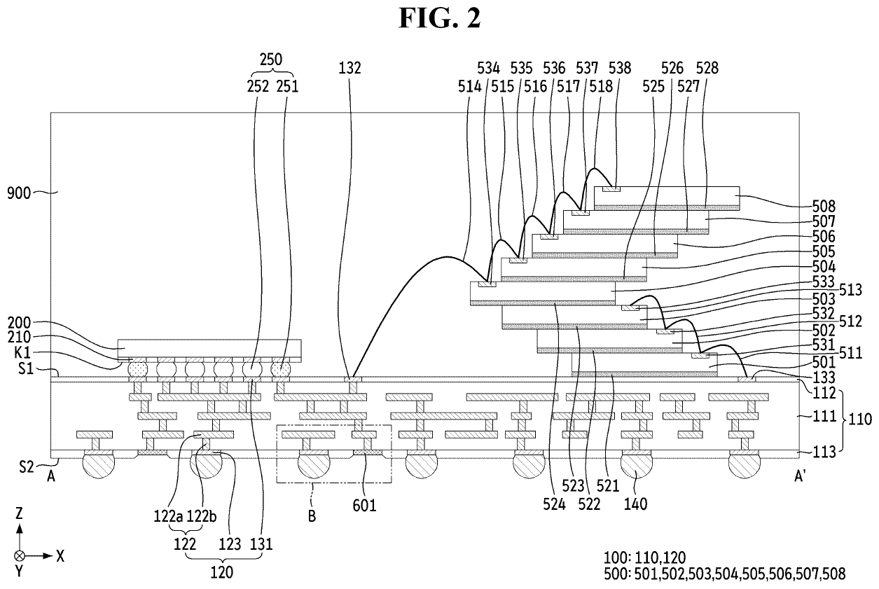

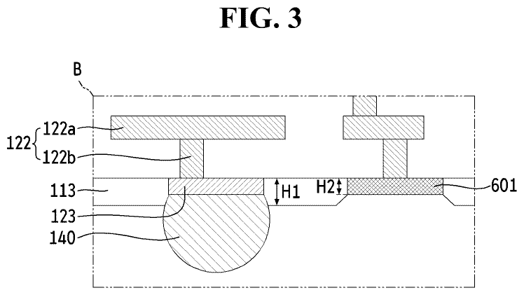

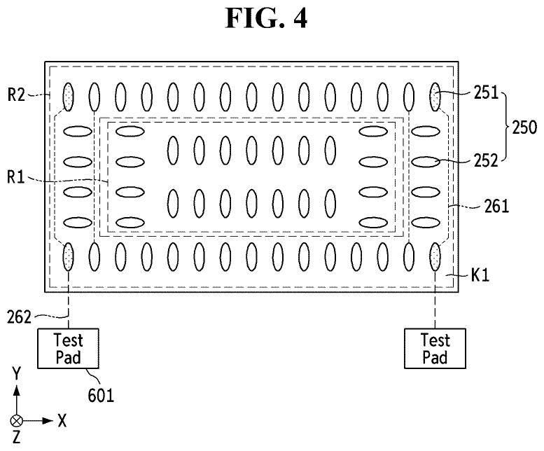

FIG. 1 is a plan view for explaining a semiconductor package according to some embodiments of the disclosure. FIG. 2 is a cross-sectional view taken along A-A′ of FIG. 1 according to some embodiments of the disclosure. FIG. 3 is an enlarged view of a portion B of FIG. 2 according to some embodiments of the disclosure. FIG. 4 is a diagram showing a connection relationship between a lower surface of a controller of FIG. 1 and a test pad according to some embodiments of the disclosure.

Referring to FIGS. 1 to 4, the semiconductor package according to some embodiments of the disclosure may include a package substrate 100, a controller 200, a plurality of bumps 250, a semiconductor chip structure 500, an external connection terminal 140, a test pad 601, and an encapsulant 900. For reference, for convenience of explanation, FIG. 1 shows a simplified view except the encapsulant 900. For convenience of explanation, FIG. 4 shows the test pad 601 provided on the lower surface S2 of the package substrate 100 in a block form.

The package substrate 100 may include a wiring structure for a package. For example, the package substrate 100 may include, but is not limited to, a printed circuit wiring structure (PCB), a ceramic wiring structure, or the like. According to another example, the package substrate 100 may be a wiring structure for a wafer-level package WLP fabricated at a wafer level. The package substrate 100 may include an upper surface S1 and a lower surface S2 that are opposite to each other. That is, the upper surface S1 and the lower surface S2 of the package substrate 100 face opposite direction.

The package substrate 100 may extend in a first direction X and a second direction Y. The first direction X and the second direction Y may each mean a direction parallel to the upper surface S1 of the package substrate. A third direction Z may mean a direction that intersects each of the first direction X and the second direction Y, and perpendicular to the upper surface S1 of the package substrate.

The package substrate 100 may include an insulating film structure 110 and a wiring structure 120. The insulating film structure 110 may include an insulating film 111, an upper passivation film 112, and a lower passivation film 113. However, the disclosure is not limited thereto, and as such, the insulating film structure 110 may include a plurality of layers. For example, the insulating film structure 110 may include a plurality of insulating film layers. The wiring structure 120 may include a first upper substrate pad 131, a wiring layer 122, and a lower substrate pad 123. However, the disclosure is not limited thereto, and as such, the wiring structure 120 may include a plurality of wiring layers.

The package substrate 100 may be, for example, a printed circuit board (PCB) or a ceramic substrate. However, the disclosure are not limited thereto, and as such, the package substrate 100 may be formed in another manner.

The insulating film structure 110 may be made up of at least one material selected from a phenolic resin, an epoxy resin, and a polyimide. For example, the insulating film structure 110 may include, but is not limited to, at least one material selected from FR-4, tetrafunctional epoxy, polyphenylene ether, epoxy/polyphenylene oxide, BT (bismaleimide triazine), thermount, cyanate ester, polyimide, and liquid crystal polymer.

According to an embodiment, a solder resist may be provided on the insulating film 111. For example, the surface of the insulating film 111 may be covered with a solder resist. That is, the upper passivation film 112 and the lower passivation film 113 formed on the surface of the insulating film 111 may be solder resist. However, the disclosure are not limited thereto, and as such, according to another embodiment, another material may be provided on the insulating film 111.

Although the package substrate 100 is shown as being a single film, this is only for convenience of explanation. As another example, the package substrate 100 may be configured as multiple layers and may form the wiring layers 122 of the multiple layers.

The wiring structure 120 may be provided in the insulating film structure 110. For example, the wiring structure 120 may be provided inside the insulating film structure 110. The wiring layer 122 may electrically connect the first upper substrate pad 131 and the lower substrate pad 123.

The wiring layer 122 may include a plurality of wiring patterns 122a, and a plurality of vias 122b. For example, each of the plurality of vias 122b may connect to a respective one of the wirings. The plurality of wiring patterns 122a may extend in the first direction X, and the plurality of vias 122b may extend in the third direction Z. The first upper substrate pad 131, the wiring layer 122, and the lower substrate pad 123 may include a conductive material. For example, the first upper substrate pad 131, the wiring layer 122, and the lower substrate pad 123 may include, but is not limited to, gold (Au), silver (Ag), copper (Cu), nickel (Ni), or aluminum (Al).

In some embodiments, the external connection terminal 140 and the test pad 601 may be provided on the lower surface S2 of the package substrate 100. The external connection terminal 140 may be attached to the lower substrate pad 123. The external connection terminal 140 may come into contact with the lower substrate pad 123. The external connection terminal 140 may be provided below the lower substrate pad 123. The test pad 601 may be provided to be spaced apart from the external connection terminal 140 in the first direction X. A part of the test pad 601 may be provided to overlap the controller 200 in the third direction Z, and another part of the test pad 601 may be provided not to overlap the controller 200 in the third direction Z.

The external connection terminal 140 may include a solder ball or a solder bump. The external connection terminal 140 may have, for example, but is not limited to, a spherical shape or an elliptical spherical shape. However, the number, interval, disposition, shape, and the like of the external connection terminal 140 are not limited to those shown in the drawings, and as such, according to another embodiment, the number, interval, disposition, shape, and the like of the external connection terminal 140 may vary depending on the design. The external connection terminal 140 may include, for example, but is not limited to, tin (Sn), indium (In), bismuth (Bi), antimony (Sb), copper (Cu), silver (Ag), zinc (Zn), lead (Pb), and combinations thereof.

The external connection terminal 140 may electrically connect the wiring structure 120 to an external device. Thus, the external connection terminal 140 may provide (or input) an electrical signal to the wiring structure 120 or provide (or output) the electrical signal provided from the wiring structure 120 to an external device.

For example, the external connection terminal 140 may provide an electrical signal for the semiconductor chip structure 500. The external connection terminal 140 may provide a power signal and a ground signal of the semiconductor chip structure 500 to the wiring structure 120. The external connection terminal 140 may receive a signal that is input to the semiconductor chip structure 500. The external connection terminal 140 may receive a signal that is output from the semiconductor chip structure 500.

The test pad 601 may be a pad for performing electrical testing on the controller 200. Referring to FIG. 3, a thickness H2 of the test pad 601 in the third direction Z may be smaller than a thickness H1 of the thickest portion of the thickness of the lower passivation film 113 in the third direction Z. In other words, the thickness of the lower passivation film 113 may be the same as or larger than the thickness of the test pad 601.

A first upper substrate pad 131, a second upper substrate pad 132, and a third upper substrate pad 133 may be provided on the upper surface S1 of the package substrate 100. The first upper substrate pad 131 may electrically connect the package substrate 100 to the controller 200 to be described below. The second upper substrate pad 132 and the third upper substrate pad 133 may electrically connect the package substrate 100 to the semiconductor chip structure 500 to be described below.

The controller 200 may be provided on the upper surface S1 of the package substrate 100. The controller 200 may be mounted on the package substrate 100 by a flip-chip bonding method. For reference, the flip-chip bonding method means a packaging method in which a semiconductor chip and a semiconductor chip pad are electrically connected through bumps.

The controller 200 may control the semiconductor chip structure 500 to be described below. The controller 200 may be, for example, but is not limited to, an application processor (AP) such as a central processing unit (CPU), a graphic processing unit (GPU), a field-programmable gate array (FPGA), a digital signal processor, an encryption processor, a micro-processor, a micro-controller, and an application-specific integrated circuit (ASIC).

According to an embodiment, a plurality of bumps 250 may be provided between the upper surface S1 of the package substrate 100 and the controller 200. In other words, the plurality of bumps may be provided between the upper surface S1 of the package substrate 100 and a lower surface K1 of the controller 200. The bumps 250 may include a test bump 251 and a connection bump 252. For example, the bumps 250 may include a plurality of test bumps 251 and a plurality of connection bumps 252. The connection bump 252 is electrically connected to the external connection terminal 140 by the wiring structure 120. The test bump 251 is not electrically connected to the external connection terminal 140 by the wiring structure 120. The test bump 251 is electrically connected to the test pad 601 by the wiring structure 120. For example, the test bump 251 is electrically connected to the outside via a different and/or s separate terminal (e.g., test pad 601) that the external connection terminal 140. The test bump 251 and the connection bump 252 may include, but are not limited to, tin (Sn), indium (In), bismuth (Bi), antimony (Sb), copper (Cu), silver (Ag), zinc (Zn), lead (Pb), and combinations thereof. The test bump 251 and the connection bump 252 may include, but are not limited to, the same material. As another example, the test bump 251 and the connection bump 252 may each include different materials.

The test bump 251 and the connection bump 252 may have the same size, but the embodiment of the disclosure is not limited thereto. As another example, the test bump 251 and the connection bump 252 may have different sizes.

The connection bump 252 may receive an input signal to the controller 200 from the outside through the external connection terminals 140 and transmit the input signal to the controller 200. For example, the connection bump 252 may receive the input signal from an external device. The connection bump 252 may provide an output signal for the controller 200 to the outside through the external connection terminals 140.

The test bump 251 may receive an input signal to the controller 200 from the outside through the external connection terminals 140, and do not transmit it to the controller 200. The test bump 251 may not supply an output signal for the controller 200 to the outside through the external connection terminals 140. The test bump 251 may be a pad for electrical testing on the controller 200.

The controller pads 210 may be provided on the lower surface K1 of the controller 200. The controller pad 210 is connected to one of the test bump 251 and the connection bump 252 to be described below, and may electrically connect the controller 200 to the test pad 601 and the external connection terminal 140.

Referring to FIG. 4, the lower surface K1 of the controller 200 may include a first region R1 and a second region R2. The first region R1 may be surrounded by the second region R2. The connection bump 252 may be provided in at least one of the first region R1 and the second region R2. The connection bump 252 may include an elongated shape in the first direction X and an elongated shape in the second direction Y. The test bump 251 may include, but is not limited to, an elongated shape in the second direction Y. As another example, the test bump 251 may include a first test bump 251a and a second test bump 251b. The first test bump 251a and the second test bump 251b may include an elongated shape in the first direction X. According to an embodiment, the test bump 251 may include a plurality of test bumps 251 provided to be parallel to each other.

The test bump 251 is provided in the second region R2. The test bump 251 is provided in the second region R2, and may detect a warpage phenomenon that occurs in the second region R2 of the controller 200.

In an example case in which the controller 200 includes a rectangular shape in a plan view, the plurality of test bumps 251 may be provided adjacent to each corner of the controller 200. For example, the two test bumps 251 may be electrically connected to each other by a first connection line 261. The first connection line 261 may be, for example, an on-chip connection line connected through an internal wiring of the controller 200. The test bumps 251 and the test pads 601 may be electrically connected to each other by a second connection line 262. The second connection line 262 may be, for example, an off-chip connection line connected through an external wiring of the controller 200. For example, the second connection line 262 may be a connection line connected through the package substrate 100.

Although FIG. 4 shows a case where the plurality of bumps 250 are regularly provided at regular intervals on the lower surface K1 of the controller 200, the embodiment of the disclosure is not limited thereto. As another example, the plurality of bumps 250 may be provided irregularly, rather than being symmetrical vertically or horizontally.

The semiconductor chip structure 500 may be mounted on the upper surface of the package substrate 100 by a wire bonding method. The semiconductor chip structure 500 may be provided to be spaced apart from the controller 200. The semiconductor chip structure 500 may include a structure in which a plurality of semiconductor chips are sequentially stacked by a wire bonding method. For reference, the wire bonding method refers to a packaging method which uses wires as wiring.

The semiconductor chip structure 500 may include a plurality of semiconductor chips. The semiconductor chip structure 500 may be a structure in which the plurality of semiconductor chips is sequentially stacked in a cascade format. The semiconductor chip structure 500 may be connected to the upper substrate pad 130 by a chip pad 530 and a bonding wire 510. The semiconductor chip structure 500 may include a first semiconductor chip 501, a second semiconductor chip 502, a third semiconductor chip 503, a fourth semiconductor chip 504,a fifth semiconductor chip 505, a sixth semiconductor chip 506, a seventh semiconductor chip 507, and an eight semiconductor chip 508. The chip pads 530 may include a first chip pad 531, a second chip pad 532, a third chip pad 533, a fourth chip pad 534, a fifth chip pad 535, a sixth chip pad 536, a seventh chip pad 537, and an eighth chip pad 538. The bonding wires 510 may include a first bonding wire 511, a second bonding wire 512, a third bonding wire 513, a fourth bonding wire 514, a fifth bonding wire 515, a sixth bonding wire 516, a seventh bonding wire 517, and an eighth bonding wire 518. The upper substrate pads 130 may include a first upper substrate pad 131, s second upper substrate pad 132, and a third upper substrate pad 133.

The first to eighth semiconductor chips 501, 502, 503, 504, 505, 506, 507, and 508 may be sequentially stacked to form the semiconductor chip structure 500. Although eight semiconductor chips are shown in FIG. 2, the disclosure is not limited thereto, and as such, according to another example, the semiconductor chip structure 500 may include seven or less semiconductor chips, or may include nine or more semiconductor chips.

The first to eighth semiconductor chips 501, 502, 503, 504, 505, 506, 507, and 508 may be memory semiconductor chips. The memory semiconductor chips may be, for example, volatile memories such as a dynamic random access memory (DRAM) or a static random access memory (SRAM). Alternatively, the memory semiconductor chips included in the first to eighth semiconductor chips 501, 502, 503, 504, 505, 506, 507, and 508 may be a non-volatile memory such as a flash memory, a phase-change random access memory (PRAM), a magnetic random access memory (MRAM), a ferroelectric random access memory (FeRAM) or a resistive random access memory (RRAM).

Although the first to eighth semiconductor chips 501, 502, 503, 504, 505, 506, 507, and 508 may include the same type of memory, the embodiment of the disclosure is not limited thereto. As another example, the first to eighth semiconductor chips 501, 502, 503, 504, 505, 506, 507, and 508 may include different memories from each other.

Each of the first to eighth semiconductor chips 501, 502, 503, 504, 505, 506, 507, and 508 may be attached to a structure provided below by a respective one of a first adhesive surface 521, a second adhesive surface 522, a third adhesive surface 523, a fourth adhesive surface 524, a fifth adhesive surface 525, a sixth adhesive surface 526, a seventh adhesive surface 527, and an eighth adhesive surface 528. For example, the first semiconductor chip 501 may be attached onto the package substrate 100 by the first adhesive surface 521. The second semiconductor chip 502 may be attached onto the upper surface of the first semiconductor chip 501 by the second adhesive surface 522.

The first to eighth adhesive surfaces 521, 522, 523, 524, 525, 526, 527, and 528 may serve to insulate the first to eighth semiconductor chips 501, 502, 503, 504, 505, 506, 507, and 508 from the structure provided below the first to eighth semiconductor chips 501, 502, 503, 504, 505, 506, 507, and 508. For example, the first adhesive surface 521 may insulate the first semiconductor chip 501 from the package substrate 100. The second adhesive surface 522 may insulate the second semiconductor chip 502 from the first semiconductor chip 501.

The first to eighth adhesive surfaces 521, 522, 523, 524, 525, 526, 527, and 528 may be, for example, a direct adhesive film (DAF) or a film over wire (FOW). The first to eighth adhesive surfaces 521, 522, 523, 524, 525, 526, 527, and 528 may include, for example, an insulating polymer. As another example, the first to eighth adhesive surfaces 521, 522, 523, 524, 525, 526, 527, and 528 may include an epoxy-based resin and a filler.

For example, the filler may use at least one or more selected from a group including silica (SiO₂), alumina (Al₂O₃), silicon carbide (SiC), barium sulfate (BaSO₄), talc, mud, mica powder, aluminum hydroxide (AlOH₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃) and calcium zirconate (CaZrO₃). On the other hand, the material of the filler is not limited thereto, and the filler may include a metal material and/or an organic material.

Each of the first to eighth semiconductor chips 501, 502, 503, 504, 505, 506, 507, and 508 may be electrically connected to the structure provided below by the first to eighth chip pads 531, 532, 533, 534, 535, 536, 537, and 538 and the first to eighth bonding wires 511, 512, 513, 514, 515, 516, 517, and 518. For example, the first semiconductor chip 501 may be electrically connected to the package substrate 100 by the first chip pad 531, the first bonding wire 511, and the third upper substrate pad 133. The first semiconductor chip 501 may be electrically connected to the second semiconductor chip 502 by the first chip pad 531, the second bonding wire 512, and the second chip pad 532. As another example, the fourth semiconductor chip 504 may be electrically connected to the package substrate 100 by the fourth chip pad 534, the fourth bonding wire 514, and the second upper substrate pad 132.

The first to eighth chip pads 531, 532, 533, 534, 535, 536, 537, and 538 may include, for example, but are not limited to, copper (Cu), copper alloy, nickel (Ni), palladium (Pd), platinum (Pt), gold (Au), cobalt (Co), and combinations thereof. The first to eighth bonding wires 511, 512, 513, 514, 515, 516, 517, and 518 may include a metal. For example, the first to eighth bonding wires 511, 512, 513, 514, 515, 516, 517, and 518 may include at least one of gold (Au) and copper (Cu).

The encapsulant 900 may be provided on the package substrate 100, the controller 200, and the semiconductor chip structure 500. For example, the encapsulant 900 may cover the upper surface of the package substrate 100, the controller 200, and the semiconductor chip structure 500. The encapsulant 900 may include, for example, but is not limited to, an insulating polymer material such as epoxy molding compound (EMC). The encapsulant 900 may include, but is not limited to, a thermosetting resin such as an epoxy resin, a thermoplastic resin such as polyimide, or a resin containing a reinforcing material such as a filler therein, for example, ABF, FR-4, or BT resin.

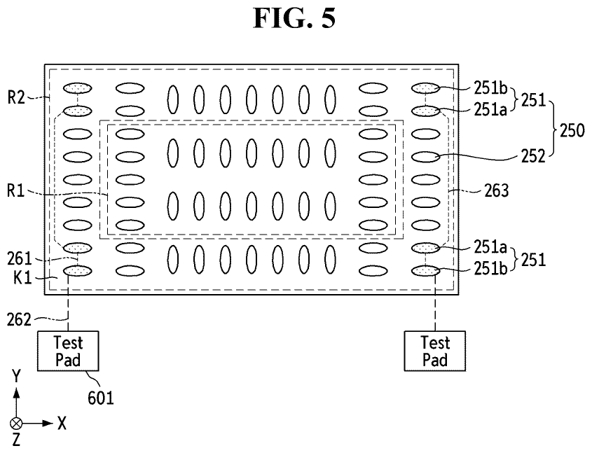

FIG. 5 is a diagram showing a connection relationship between the lower surface of the controller of FIG. 1 and the test pad according to another embodiment of the disclosure. For convenience of explanation, FIG. 5 will mainly explain the differences from those explained in FIGS. 1 to 4.

Referring to FIG. 5, the test bumps 251 provided on the controller 200 of the semiconductor package according to another embodiment of the disclosure may include a first test bump 251a and a second test bump 251b.

The first test bump 251a may be provided closer to the first region R1 than the second test bump 251b. The first test bump 251a and the second test bump 251b may include, but are not limited to, an elongated shape in the first direction X. As another example, the first test bump 251a and the second test bump 251b may include an elongated shape in the second direction Y. The first test bump 251a and the second test bump 251b may be provided to be parallel to each other.

The first test bump 251a and the second test bump 251b may be electrically connected to each other by a first connection line 261. The first connection line 261 may be, for example, an on-chip connection line connected through an internal wiring of the controller 200.

The first test bump 251a may include two first test bumps 251a and the second test bump 251b may include two second test bumps 251b. However, the disclosure is not limited thereto, and as such, the number of the test bumps may vary. The two first test bumps 251a may be electrically connected to each other by a third connection line 263. The third connection line 263 may be, for example, an off-chip connection line connected through an external wiring of the controller 200.

The second test bump 251b and the test pad 601 may be electrically connected by a second connection line 262. The second connection line 262 may be, for example, an off-chip connection line connected through an external wiring of the controller 200.

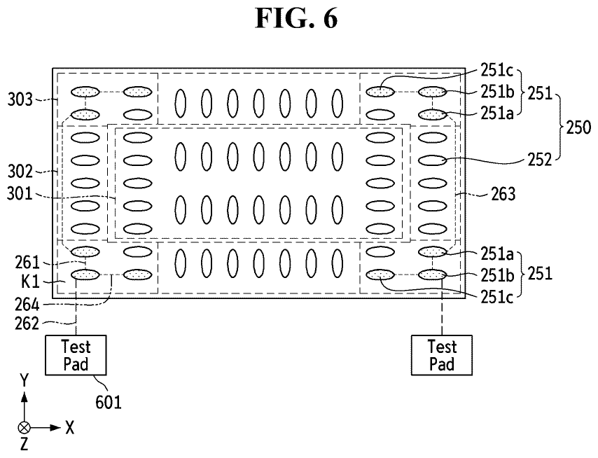

FIG. 6 is a diagram showing a connection relationship between the lower surface of the controller of FIG. 1 and the test pad according to another embodiment of the disclosure. For convenience of explanation, FIG. 6 will mainly explain differences from those explained in FIGS. 1 to 4.

Referring to FIG. 6, the lower surface K1 of the controller 200 of the semiconductor package according to another embodiment of the disclosure may include a central part 301, a peripheral part 302, and a corner part 303.

The central part 301 of the controller 200 may be surrounded by the peripheral part 302 and the corner part 303. The corner part 303 may include four corners of the rectangular controller 200. The corner part 303 may be provided between a plurality of peripheral parts 302 spaced apart from each other. In other words, the peripheral parts 302 and the edge parts 303 may be provided alternately and repeatedly.

The test bump 251 may include a first test bump 251a, a second test bump 251b, and a third test bump 251c. The second test bump 251b may be provided to be surrounded by the first test bump 251a and the third test bump 251c. The first test bump 251a, the second test bump 251b, and the third test bump 251c may include, but are not limited to, an elongated shape in the first direction X. As another example, the first test bump 251a, the second test bump 251b, and the third test bump 251c may include an elongated shape in the second direction Y. The first test bump 251a, the second test bump 251b, and the third test bump 251c may be provided to be parallel to each other.

The first test bump 251a and the second test bump 251b may be electrically connected to each other by a first connection line 261. The first connection line 261 may be, for example, an on-chip connection line connected through the internal wiring of the controller 200.

The third test bump 251c and the second test bump 251b may be electrically connected to each other by a fourth connection line 264. The fourth connection line 264 may be, for example, an on-chip connection line connected through an internal wiring of the controller 200.

The first test bump 251a may include two first test bumps 251a, the second test bump 251b may include two second test bumps 251b, and the third test bump 251c may include two third test bumps 251c. However, the disclosure is not limited thereto, and as such, the number of the test bumps may vary. The two first test bumps 251a may be electrically connected to each other by a third connection line 263. The third connection line 263 may be, for example, an off-chip connection line connected through an external wiring of the controller 200.

The second test bump 251b and the test pad 601 may be electrically connected to each other by a second connection line 262. The second connection line 262 may be, for example, an off-chip connection line connected through an external wiring of the controller 200. Although FIG. 6 shows a case where the second test bump 251b and the test pad 601 are connected to each other, the embodiment of the disclosure is not limited thereto. As another example, the third test bump 251c and the test pad 601 may be connected to each other.

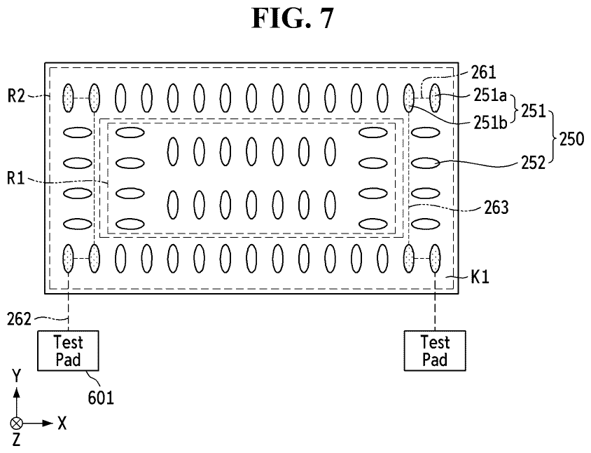

FIG. 7 is a diagram showing a connection relationship between the lower surface of the controller of FIG. 1 and the test pad according to another embodiment of the disclosure. For convenience of explanation, FIG. 7 will mainly explain differences from those explained in FIGS. 1 to 4.

Referring to FIG. 7, the test bump 251 provided on the controller 200 of the semiconductor package according to another embodiment of the disclosure may include a first test bump 251a and a second test bump 251b.

The first test bump 251a may be provided farther away from the first region R1 than the second test bump 251b. The first test bump 251a and the second test bump 251b may include, but are not limited to, an elongated shape in the second direction Y. As another example, the first test bump 251a and the second test bump 251b may include an elongated shape in the first direction X. The first test bump 251a and the second test bump 251b may be provided to be parallel to each other.

The first test bump 251a and the second test bump 251b may be electrically connected to each other by a first connection line 261. The first connection line 261 may be, for example, an on-chip connection line connected through an internal wiring of the controller 200.

The two second test bumps 251b may be electrically connected to each other by a third connection line 263. The third connection line 263 may be, for example, an off-chip connection line connected through an external wiring of the controller 200.

The first test bump 251a and the test pad 601 may be electrically connected to each other by a second connection line 262. The second connection line 262 may be an off-chip connection line connected through, for example, an external wiring of the controller 200.

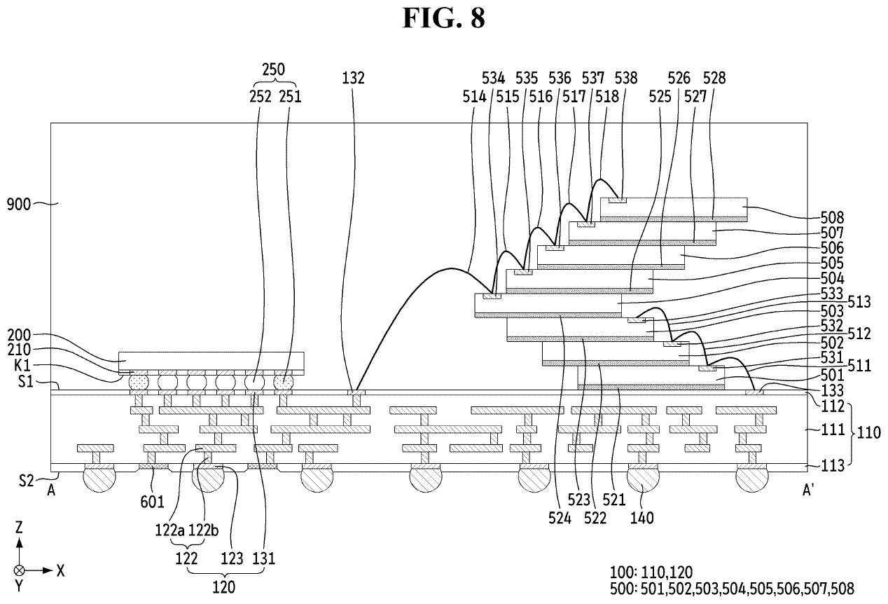

FIG. 8 is a cross-sectional view taken along line A-A′ of FIG. 1 according to another embodiment of the disclosure. For convenience of explanation, FIG. 8 will mainly explain differences from those explained in FIGS. 1 to 4.

Referring to FIG. 8, the test pad 601 may be provided to overlap the controller 200 in the third direction Z. In other words, the plurality of test pads 601 may all be provided to overlap the controller 200 in the third direction Z. Although only two test pads 601 are shown in FIG. 8, the embodiment of the disclosure is not limited thereto. As another example, three or more test pads 601 may be provided.

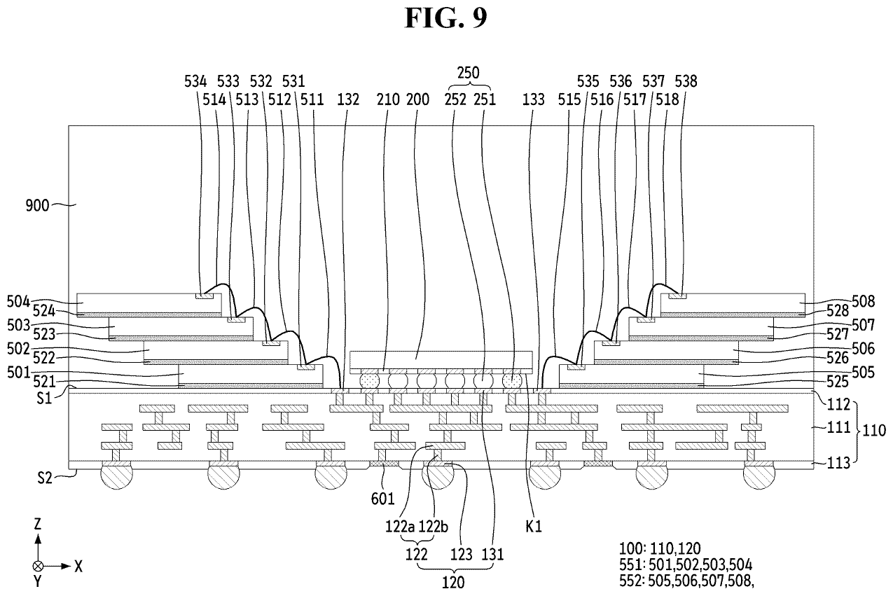

FIG. 9 is a cross-sectional view of a semiconductor package according to another embodiment of the disclosure. For convenience of explanation, FIG. 9 will mainly explain differences from those explained in FIGS. 1 to 4.

Referring to FIG. 9, the semiconductor package according to another embodiment of the disclosure may include a first semiconductor chip structure 551 and a second semiconductor chip structure 552.

The first semiconductor chip structure 551 may be mounted on the upper surface S1 of the package substrate 100 by a wire bonding method. The second semiconductor chip structure 552 may be mounted on the upper surface S1 of the package substrate 100 by a wire bonding method. Each of the first semiconductor chip structure 551 and the second semiconductor chip structure 552 may be provided to be spaced apart from the controller 200. The first semiconductor chip structure 551 and the second semiconductor chip structure 552 may be provided to be spaced apart from each other.

The first semiconductor chip structure 551 includes the first to fourth semiconductor chips 501, 502, 503, and 504, and the second semiconductor chip structure 552 may include the fifth to eighth semiconductor chips 505, 506, 507, and 508. The first semiconductor chip structure 551 may be electrically connected to the package substrate 100 by the second upper substrate pad 132. For example, the first semiconductor chip 501 may be electrically connected to the package substrate 100 through the second upper substrate pad 132, the first bonding wire 511, and the first chip pad 531. The second semiconductor chip structure 552 may be electrically connected to the package substrate 100 by the third upper substrate pad 133. For example, the fifth semiconductor chip 505 may be electrically connected to the package substrate 100 through the third upper substrate pad 133, the fifth bonding wire 515, and the fifth chip pad 535.

Although FIG. 9 shows a semiconductor chip structures including four semiconductor chips, the embodiment of the disclosure is not limited thereto. As another example, each of the first semiconductor chip structure 551 and the second semiconductor chip structure 552 may include five or more semiconductor chips. Although FIG. 9 shows a case where the first semiconductor chip structure 551 and the second semiconductor chip structure 552 include the same number of semiconductor chips, the embodiment of the disclosure is not limited thereto. As another example, the number of semiconductor chips included in the first semiconductor chip structure 551 and the second semiconductor chip structure 552 may be different from each other.

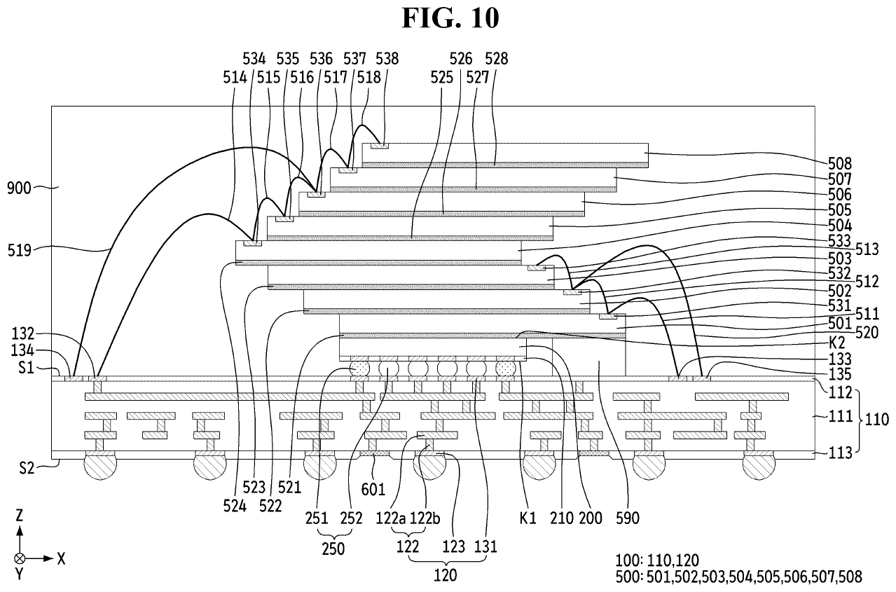

FIG. 10 is a cross-sectional view of a semiconductor package according to another embodiment of the disclosure. For convenience of explanation, FIG. 10 will mainly explain differences from those explained in FIGS. 1 to 4.

Referring to FIG. 10, a semiconductor package according to another embodiment of the disclosure may further include a support structure 590. A semiconductor chip structure 500 may be provided on the controller 200 of the semiconductor package according to another embodiment of the disclosure. The controller 200 may include an upper surface K2 and a lower surface K1 that are opposite to each other. For example, the semiconductor chip structure 500 may be mounted on the upper surface K2 of the controller 200.

A support structure 590 may be provided on the upper surface of the package substrate 100. For example, the support structure 590 may be provided to be spaced apart from the controller 200. The support structure 590 may be provided between the semiconductor chip structure 500 and the package substrate 100. The semiconductor chip structure 500 may be fixed onto the controller 200, using the support structure 590 as a support base.

Although FIG. 10 shows that the width of the semiconductor chip structure 500 in the first direction X is larger than the width of the controller 200 in the first direction X, the disclosure is not limited thereto. As such, according to another example, the width of the semiconductor chip structure 500 in the first direction X may be smaller than the width of the controller 200 in the first direction X.

The support structure 590 may include a cured product of a thermosetting resin composition. Although FIG. 10 shows that the support structure 590 is a single layer, the embodiment of the disclosure is not limited thereto. As another example, the support structure 590 may include a multi-layer structure including a plurality of membranes and adhesive layers.

The first semiconductor chip 501 may be electrically connected to the package substrate 100 by the third upper substrate pad 133 and the fifth upper substrate pad 135. For example, the first semiconductor chip 501 may be electrically connected to the package substrate 100 by the third upper substrate pad 133, the first bonding wire 511, and the first chip pad 531. The first semiconductor chip 501 may be electrically connected to the package substrate 100 by the fifth upper substrate pad 135, the tenth bonding wire 520, and the second chip pad 532.

The fourth semiconductor chip 504 may be electrically connected to the package substrate 100 by the second upper substrate pad 132 and the fourth upper substrate pad 134. For example, the fourth semiconductor chip 504 may be electrically connected to the package substrate 100 by the second upper substrate pad 132, the fourth bonding wire 514, and the fourth chip pad 534. The fourth semiconductor chip 504 may be electrically connected to the package substrate 100 by the fourth upper substrate pad 134, the ninth bonding wire 519, and the sixth chip pad 536.

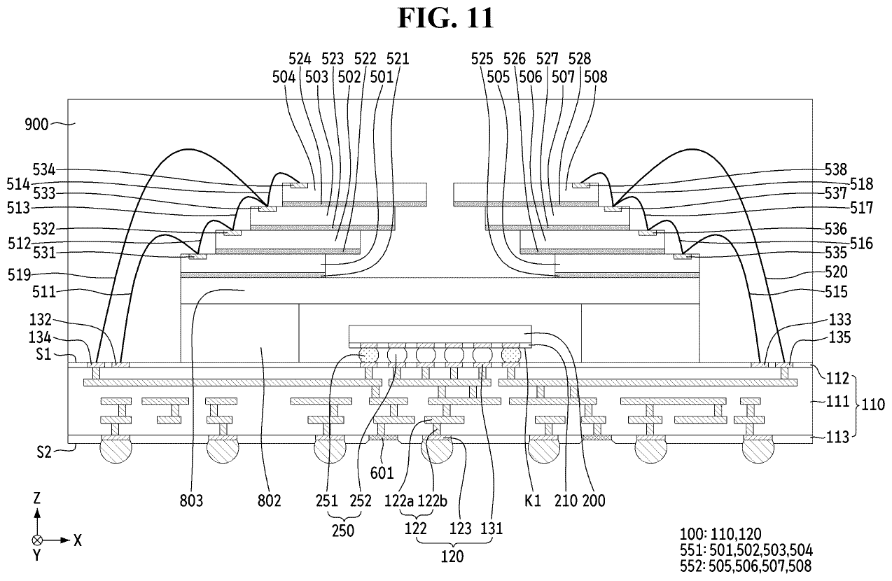

FIG. 11 is a cross-sectional view of a semiconductor package according to another embodiment of the disclosure. For convenience of explanation, FIG. 11 will mainly explain differences from those explained in FIGS. 1 to 4.

Referring to FIG. 11, a semiconductor package according to another embodiment of the disclosure may further include a first supporter 801, a second supporter 802, and a third supporter 803. The first supporter 801 and the second supporter 802 may be provided on the package substrate 100 to be spaced apart from each other with the controller 200 interposed between them. The third supporter 803 may be provided on the first supporter 801 and the second supporter 802.

The third supporter 803 may be fixed, using the first supporter 801 and the second supporter 802 as support bases. The first semiconductor chip structure 551 and the second semiconductor chip structure 552 may be provided on the third supporter 803. The first semiconductor chip structure 551 and the second semiconductor chip structure 552 may be provided to be spaced apart from each other on the third supporter 803.

The first supporter 801, the second supporter 802, and the third supporter 803 may each include a cured product of a thermosetting resin composition. Although FIG. 11 shows that the first supporter 801, the second supporter 802, and the third supporter 803 are each a single layer, the embodiment of the disclosure is not limited thereto. As another example, each of the first supporter 801, the second supporter 802, and the third supporter 803 may include a multi-layer structure including a plurality of membranes and adhesive layers.

The first semiconductor chip structure 551 may be electrically connected to the package substrate 100 by the second upper substrate pad 132 and the fourth upper substrate pad 134. For example, the first semiconductor chip 501 may be electrically connected to the package substrate 100 by the second upper substrate pad 132, the first bonding wire 511, and the first chip pad 531. The third semiconductor chip 503 may be electrically connected to the package substrate 100 by the fourth upper substrate pad 134, a ninth bonding wire 519, and the fourth chip pad 534.

The second semiconductor chip structure 552 may be electrically connected to the package substrate 100 by the third upper substrate pad 133 and the fifth upper substrate pad 135. For example, the fifth semiconductor chip 505 may be electrically connected to the package substrate 100 by the third upper substrate pad 133, a fifth bonding wire 515, and the fifth chip pad 505. The seventh semiconductor chip 507 may be electrically connected to the package substrate 100 by the fifth upper substrate pad 135, the tenth bonding wire 520, and the seventh chip pad 507.

Those skilled in the art will appreciate that many variations and modifications may be made to the preferred embodiments without substantially departing from the principles of the disclosure. Therefore, the disclosed preferred embodiments of the disclosure are used in a generic and descriptive sense only and not for purposes of limitation.

What is claimed is:

1. A semiconductor package comprising:
a package substrate comprising an insulating film and a wiring structure;
an external connection terminal provided on a first surface of the package substrate;
a test pad provided on the first surface of the package substrate, and spaced apart from the external connection terminal;
a first semiconductor chip provided on a second surface of the package substrate;
a plurality of test bumps and a plurality of connection bumps provided between the second surface of the package substrate and the first semiconductor chip; and
a second semiconductor chip provided on the second surface of the package substrate to be spaced apart from the first semiconductor chip,
wherein the first semiconductor chip comprises an on-chip connection line connected through an internal wiring,
wherein at least two of the plurality of test bumps are connected to each other by the on-chip connection line, and
wherein at least one of the plurality of connection bumps is electrically connected to the external connection terminal by the wiring structure.

2. The semiconductor package of claim 1,
wherein the first semiconductor chip comprises a first region, and a second region that surrounds the first region, and
wherein the plurality of test bumps are provided in the second region.

3. The semiconductor package of claim 2,
wherein the second region comprises a plurality of peripheral parts, and a corner part provided between the plurality of peripheral parts, and
wherein at least one of the plurality of test bumps is provided at the corner part.

4. The semiconductor package of claim 1,
wherein at least one of the plurality of test bumps is electrically connected to the test pad.

5. The semiconductor package of claim 1,
wherein the second semiconductor chip comprise a memory, and the first semiconductor chip comprises a controller configured to control the memory.

6. The semiconductor package of claim 1,
wherein the second semiconductor chip is wire-bonded to the package substrate.

7. The semiconductor package of claim 6, further comprising:
a plurality of third semiconductor chips which are sequentially stacked on the second semiconductor chip in a cascade format, and are wire-bonded to the second semiconductor chip.

8. The semiconductor package of claim 1,
wherein the test pad overlaps the first semiconductor chip in a vertical direction.

9. The semiconductor package of claim 1,
wherein the second semiconductor chip and the test pad are electrically connected by the wiring structure.

10. A semiconductor package comprising:
a package substrate comprising an insulating film and a wiring structure;
an external connection terminal provided on a first surface of the package substrate;
a test pad provided on the first surface of the package substrate, and provided to be spaced apart from the external connection terminal;
a first semiconductor chip provided on a second surface of the package substrate;
a first test bump, a second test bump, and a connection bump provided between the second surface of the package substrate and the first semiconductor chip;
a second semiconductor chip provided on the second surface of the package substrate; and
a third semiconductor chip which is provided on the second surface of the package substrate, and spaced apart from the second semiconductor chip,
wherein the first semiconductor chip comprises an on-chip connection line connected through an internal wiring,
wherein the first test bump and the second test bump are connected to each other by the on-chip connection line,
wherein the first test bump is electrically connected to the second semiconductor chip and the test pad by the wiring structure,
wherein the second test bump is electrically connected to the third semiconductor chip and the test pad by the wiring structure, and
wherein the connection bump is electrically connected to the external connection terminal by the wiring structure.

11. The semiconductor package of claim 10,
wherein the first semiconductor chip comprises a central part, a plurality of peripheral parts, and a plurality of corner parts,
wherein the plurality of peripheral parts and the plurality of corner parts are alternately provided and surround the central part, and
wherein the first test bump and the second test bump are provided on the plurality of corner parts.

12. The semiconductor package of claim 10,
wherein the first semiconductor chip comprises a first region, and a second region that surrounds the first region, and
wherein the first test bump and the second test bump are provided in the second region.

13. The semiconductor package of claim 12,
wherein the second region comprises a plurality of peripheral parts, and a corner part provided between the plurality of peripheral parts, and
wherein the first test bump is provided on the corner part.

14. The semiconductor package of claim 10,
wherein the second semiconductor chip and the third semiconductor chip are wire-bonded to the package substrate.

15. The semiconductor package of claim 10, further comprising:
a first supporter spaced apart from the first semiconductor chip, and provided on a first side of the first semiconductor chip;
a second supporter spaced apart from the first semiconductor chip, and provided on a second side of the first semiconductor chip; and
a third supporter provided on the first supporter and the second supporter,
wherein at least one of the first supporter, the second supporter, and the third supporter comprises a cured product of a thermosetting resin composition.

16. The semiconductor package of claim 10,
wherein the second semiconductor chip and the third semiconductor chip comprise a memory, and
wherein the first semiconductor chip comprises a controller configured to control the memory.

17. The semiconductor package of claim 10,
wherein the second semiconductor chip and the third semiconductor chip comprise a same type of memory.

18. The semiconductor package of claim 10, further comprising:
a molding material provided on the first semiconductor chip, the second semiconductor chip, and the third semiconductor chip on the package substrate.

19. The semiconductor package of claim 10, further comprising:
a plurality of fourth semiconductor chips stacked on the second semiconductor chip and wire-bonded to the second semiconductor chip; and
a plurality of fifth semiconductor chips stacked on the third semiconductor chip and wire-bonded to the third semiconductor chip.

20. A semiconductor package comprising:
a package substrate comprising an insulating film and a wiring structure;
an external connection terminal which is provided on a first surface of the package substrate;
a test pad which is provided on the first surface of the package substrate, and spaced apart from the external connection terminal;
a controller provided on a second surface of the package substrate, the controller comprising a first region, and a second region that surrounds the first region;
a plurality of test bumps and a plurality of connection bumps provided between the second surface of the package substrate and the controller; and
a semiconductor chip stack provided on the second surface of the package substrate to be spaced apart from the controller, the semiconductor chip stack comprising a plurality of stacked memory chips,
wherein the plurality of test bumps are provided in the second region, and electrically connected to the semiconductor chip stack and the test pad by the wiring structure,
wherein the plurality of connection bumps are electrically connected to the external connection terminal by the wiring structure,
wherein the controller comprises on-chip connection lines connected through an internal wiring,
wherein the plurality of test bumps are connected to each other by the on-chip connection lines, and
wherein the semiconductor chip stack is wire-bonded to the package substrate.
